(19) United States
(12) Patent Application Publication
(10) Pub. No.: US 2019/0025382 A1
(43) Pub. Date: Jan. 24, 2019

(54) SECONDARY BATTERY DEGRADATION ASSESSMENT DEVICE

(71) Applicant: NTN CORPORATION, Osaka (JP)

(72) Inventor: Hiroyuki YAMADA, Iwata (JP)

(73) Assignee: NTN CORPORATION, Osaka (JP)

(21) Appl. No.: 16/144,576

(22) Filed: Sep. 27, 2018

Related U.S. Application Data
(63) Continuation of application No. PCT/JP2017/011961, filed on Mar. 24, 2017.

(30) Foreign Application Priority Data
Mar. 28, 2016 (JP) 2016-063179
Sep. 21, 2016 (JP) 2016-183589

(51) Int. Cl. G01R 31/36

(52) U.S. Cl. CPC G01R 31/3679; G01R 31/3665; G01R 31/3648; G01R 31/3689

(57) ABSTRACT

This secondary battery degradation determination device includes: a voltage measurement section to measure DC voltage between terminals of a battery; a discharging circuit composed of a current limiting resistor and a switch and connected in parallel to the battery; a discharge management section; and a degradation determination section. The discharge management section starts discharge when DC voltage is higher than an upper limit value, monitors DC voltage during this time, and stops the discharge when the DC voltage has become lower than a lower limit value. Battery DC voltage is compared with a set value of voltage, and when the battery DC voltage is higher than this set value, the battery is discharged. The degradation determination section measures a discharge frequency in the discharging circuit caused by control by the discharge management section, and determines degradation of the battery on the basis of the discharge frequency.

### CROSS REFERENCE TO THE RELATED APPLICATION

This application is a continuation application, under 35 U.S.C. § 111(a), of international application No. PCT/JP2017/011961, filed Mar. 24, 2017, which is based on and claims Convention priority to Japanese patent applications No. 2016-063179, filed Mar. 28, 2016, and No. 2016-183589, filed Sep. 21, 2016, the entire disclosures of which are herein incorporated by reference as a part of this application.

### BACKGROUND OF THE INVENTION

### Field of the Invention

The present invention relates to a degradation assessment or determination device, for a secondary battery, which assesses or determines degradation of a battery, and which is used in data centers, mobile phone base stations, or other various types of emergency power supplies for which stable electric power supply is required, or in general power supplies in which a plurality of batteries are connected in series.

### Description of Related Art

In data centers, mobile phone base stations, or the like, stable supply of electric power is important. Although a commercial AC power supply is used during steady operation, such a data center, a mobile phone base station, or the like is provided with an emergency power supply in which a secondary battery is used, as an uninterruptible power supply device, for a case where the commercial AC power supply stops. Charging methods for the emergency power supply includes: a trickle charging type in which charging is carried out with a minute current by use of a charging circuit during steady operation; and a float charging type in which a load and a secondary battery are connected in parallel to a rectifier, and charging is carried out while the load is being operated with a constant current being applied. In general, the trickle charging type is more often employed in the emergency power supply.

The emergency power supply is required to have voltage and current that allow driving of a load that is driven by the commercial power supply. Since a single secondary battery (also referred to as battery) has low voltage and a small capacity, the emergency power supply is configured such that a plurality of battery groups are connected in parallel, each battery group including a plurality of batteries that are connected in series. The individual battery is a lead storage battery, a lithium ion battery, or the like.

In such an emergency power supply, the voltages of the batteries decrease due to degradation. Therefore, in order to ensure reliability, it is desired that degradation determination of each battery is performed and any battery that has been degraded is replaced. However, there has been no proposal of a device that can perform accurate degradation determination on a large number of batteries in a large-scale emergency power supply such as in a data center, a mobile phone base station, or the like.

Examples of proposals regarding conventional battery degradation determination include: a proposal of an on-vehicle battery checker that performs measurement on the entire battery (for example, Patent Document 1); a proposal in which a pulse-shaped voltage is applied to a battery and the internal impedance of the entire battery is calculated from an input voltage and a response voltage (for example, Patent Document 2); and a proposal of a method in which internal resistance of each of individual cells connected in series in a battery is measured, whereby degradation is determined (for example, Patent Document 3). For measurement of the internal resistance of each individual cell, an AC 4-terminal-method is used. As a handy checker that measures a very small resistance value such as internal resistance of a battery, an AC 4-terminal-method battery tester has been commercialized (for example, Non-Patent Document 1).

In Patent Documents 1 and 2 mentioned above, wireless data transmission is also proposed, and in addition, reduction of handling of cables and manual work, and data management by computers are also proposed.

### RELATED DOCUMENT

### Patent Document

[Patent Document 1] JP Laid-open Patent Publication No. H10-170615
[Patent Document 2] JP Laid-open Patent Publication No. 2005-100969
[Patent Document 3] JP Laid-open Patent Publication No. 2010-164441

### Non-Patent Document

[Non-Patent Document 1] AC 4-terminal-method battery tester, internal resistance measuring instrument IW7807-13P (Rev. 1.7.1, Feb. 16, 2015, Tokyo Devices) (https://tokyodevices.jp/system/attachments/files/000/000/298/original/IW7807-BP-F_MANUAL.pdf)

In each of the conventional secondary battery degradation determination devices, current is applied to each battery, voltage between terminals is measured, and internal resistance is calculated, and thus, the configuration of sensors is complicated. In particular, an emergency power supply is composed of a large number of batteries, and thus, if the configuration of each sensor which performs measurement on an individual battery is complicated, the whole device as a degradation determination device becomes large-sized, which causes high costs. The conventional handy checker (Non-Patent Document 1) requires too many measurement positions, and thus, is not practical for an emergency power supply in which tens and hundreds of batteries are connected.

Most emergency power supplies have batteries connected in series to be used, and charged states thereof are always maintained by float charging or trickle charging. When a battery is degraded, internal resistance increases, and thus, in a case of a large number of batteries connected in series, direct-current (DC) voltage between terminals of a battery that has been degraded increases. Therefore, if DC voltage of each individual battery is measured, degradation of each battery can be determined to some extent. However, variation in battery DC voltage is also caused by other factors, and thus, degradation of the battery cannot be accurately determined when done only through measurement of the voltage between terminals.

### SUMMARY OF THE INVENTION

An object of the present invention is to provide a secondary battery degradation determination device which has a simple configuration, which can determine degradation of a secondary battery accurately to some extent, and which is also suitable for degradation determination in an emergency power supply in which a large number of batteries are connected.

Hereinafter, in order to facilitate understanding of the present invention, the present invention will be described with reference to the reference numerals used in embodiments for the sake of convenience.

A secondary battery degradation determination device of the present invention includes: a voltage measurement section 21 configured to measure DC voltage between terminals of a battery 2 which is a secondary battery; a discharging circuit 35 which is a series circuit of a current limiting resistor 36 and a switch 37 and connected in parallel to the battery 2; a discharge management section 22 configured to monitor battery DC voltage measured by the voltage measurement section 21, turn on the switch 37 to discharge the battery 2 when the battery DC voltage is higher than a set upper limit value, monitor the battery DC voltage while the switch 37 is on, and turn off the switch 37 to stop the discharge when the battery DC voltage has become lower than a set lower limit value; and a degradation determination section 19, 19A, configured to measure a discharge frequency in the discharging circuit 35 caused as a result of control by the discharge management section 22, and determine degradation of the battery 2 on the basis of the discharge frequency.

When the battery DC voltage is monitored, the switch 37 may be temporarily turned off to stop the discharge.

The “upper limit value” and the “lower limit value” are values determined as desired, and are preferably set, for example, to the upper limit and the lower limit, respectively, in the range of normal voltage in which range degradation of the battery 2 has not occurred. In general, in a case of a battery of 2 V, the range of normal voltage is 1.8 to 2.23 V. Herein, with respect to the magnitude of a value used as a reference, the expression “when . . . is higher than an upper limit value” (or “become lower than a lower limit value”) or the like may be construed in the meaning of “not less than” (or “less than”) or “greater than”/“exceeding” (or “not greater than”).

If each individual battery DC voltage is measured, degradation of the battery 2 can be determined to some extent. However, variation in battery DC voltage is also caused by other factors, and thus, degradation of the battery cannot be accurately determined when done only through measurement of the voltage between terminals. In the present invention, battery DC voltage is measured in a charged state under application of voltage or the like, and when the battery DC voltage is higher than the upper limit value, energy is consumed by the current limiting resistor 36 through discharge, and when the battery DC voltage has become lower than the lower limit value, the discharge is stopped, and overcharge is prevented. Through repetition of these operations, degradation of the battery 2 is determined on the basis of discharge frequency. When the discharge frequency is high, it is possible to determine that degradation has occurred. That is, when the battery has been degraded, internal resistance increases, and thus, among a plurality of batteries connected in series, voltage of a degraded battery increases. When the voltage is high, discharge frequency increases, and thus it is determined that degradation has occurred.

In this manner, discharge start at the upper limit value of voltage and discharge stop at the lower limit value of voltage are repeated, and the determination is performed on the basis of the discharge frequency. Thus, degradation of the battery can be determined accurately to some extent. Since no current application means used for measurement is required, the secondary battery degradation determination device has a simple structure, and can be produced at low cost. It should be noted that the “discharge frequency” may be managed in terms of the number of tunes of discharge or a discharge interval.

For example, as a process of degradation determination based on the discharge frequency, the degradation determination section 19, 19A may measure the number of times of discharge performed in a set time period, and determine that the battery has been degraded when the number of times of discharge is greater than a set number of times (corresponding to the example shown in FIG. 5A and FIG. 5B and the example shown in FIG. 6). When the determination is performed on the basis of the number of times of discharge, degradation of the battery can be determined in a simple manner.

As degradation determination based on the discharge frequency, the degradation determination section 19, 19A may measure a discharge interval between immediately-preceding discharge and discharge at the present time, and determine that the battery has been degraded when the discharge interval is shorter than a set interval (corresponding to the example shown in FIG. 7 and the example shown in FIG. 8). A short discharge interval means a high frequency of discharge. Therefore, also when the determination is performed on the basis of the discharge interval, degradation of the battery can be determined in a simple manner.

In the present invention, as degradation determination based on the discharge frequency, the degradation determination section 19 may measure a switching time period which is a time period between start of the discharge and stop of the discharge, and determine that the battery has been degraded when a discharge time period which is the switching time period is shorter than a set time period (corresponding to the example shown in FIG. 9 and the example shown in FIG. 10). The discharge time period which is the switching time period also indicates the discharge frequency, and thus degradation determination can be performed.

In the present invention, as a process of degradation determination based on the discharge frequency, when the discharge management section 22 starts discharge because the battery DC voltage is higher than the upper limit value, then, temporarily turns off the switch 37 at a constant interval, maintains the switch 37 in an off-state when the battery DC voltage measured by the voltage measurement section 21 has become lower than the lower limit value, and repeats processes of the voltage monitoring, the comparison with the upper limit value, the temporary turning off of the switch, the comparison with the lower limit value, and the maintaining of the switch in the off-state, and if the number of times of discharge in a set time period has become greater than a set value, the degradation determination section 19 may determine that the battery has been degraded (corresponding to the example shown in FIG. 11). Thus, also in a case where the switch is temporarily turned off to perform voltage measurement while the battery is being discharged and where the number of times of discharge in a set time period is compared with a set value, degradation of the battery 2 can be accurately determined. The “set value” in “the number of times . . . greater than a set value” is a value that is set as desired in the design.

In the present invention, the degradation determination device is a device configured to determine degradation of each of a plurality of batteries 2 connected in series in a power supply and includes the voltage measurement section 21, the discharging circuit 35, and the discharge management section 22 for each battery. After the voltage measurement sections 21 of all of the plurality of batteries have performed voltage measurement, the degradation determination section 19, 19A may obtain an average value of measured battery DC voltages, and obtain the upper limit value and the lower limit value, using the average value as a reference. The “upper limit value and the lower limit value” may be fixed values, but there are cases appropriate battery DC voltage slightly differs depending on the individual power supply. Therefore, if the average value of battery DC voltages of all the batteries is obtained as described above, and if an upper limit value and a lower limit value of voltage for discharge and discharge stop are determined using the average value as a reference, it is possible to cause each individual power supply to perform more appropriate discharge, thereby increasing the degradation determination accuracy. For example, the upper limit value is a value that is higher by a predetermined value than the average value, and the lower limit value is a value that is lower by a predetermined value than the average value.

In the present invention, the current limiting resistor 36 and the switch 37 may be mounted on the same circuit board as that of the voltage measurement section 21. When the current limiting resistor 36 and the switch 37 are mounted on the same circuit board, the device is simplified and made compact.

In the present invention, a circuit of the current limiting resistor 36 and the switch 37 and a circuit of the voltage measurement section 21 may share a cable 38 connected to the battery. The circuit of the current limiting resistor 36 and the switch 37, and the voltage measurement section 21 are both connected to the battery. Since the connection circuit is shared by the circuit of the current limiting resistor 36 and the switch 37, and the voltage measurement section 21, cable wiring is simplified.

The secondary battery degradation determination device of the present invention may include: a plurality of voltage sensors 7 each including the voltage measurement section 21, the discharging circuit 35, and the discharge management section 22; and an information processing apparatus 11A provided single for the plurality of voltage sensors 7, configured to output operation instructions for the voltage sensors 7, perform measurement or processes regarding the voltage sensors 7, and collect data. In this configuration, it is easy to perform management or the like of control of measurement performed by a large number of voltage sensors 7 respectively connected to a large number, i.e., tens and hundreds, of batteries 2 in an emergency power supply, measurement results, and degradation determination results.

In a case where the information processing apparatus 11A is provided, the information processing apparatus 11A may include the degradation determination section 19 or a section that forms a part of the degradation determination section 19. There are cases where common processes such as average value calculation are necessary for performing degradation determination of each battery 2. If the information processing apparatus 11A, which is separate from the voltage sensor 7, is used, the common processes can be efficiently performed.

In the present invention, the secondary battery degradation determination device may include an alert section 39 configured to generate an alert, which is to be perceived by an operator (or a surveillant), when the degradation determination section 19 has determined that the battery 2 has been degraded, wherein the voltage measurement section 21, the discharging circuit 35, the discharge management section 22, the degradation determination section 19, and the alert section 39 may be housed in a common housing (not shown). In this configuration, without provision of an information processing apparatus that collects data, the sensor by itself can determine degradation of the battery 2. In addition, no wireless communication section for performing communication with the information processing apparatus is necessary.

Any combination of at least two constructions, disclosed in the appended claims and/or the specification and/or the accompanying drawings should be construed as included within the scope of the present invention. In particular, any combination of two or more of the appended claims should be equally construed as included within the scope of the present invention.

### BRIEF DESCRIPTION OF THE DRAWINGS

In any event, the present invention will become more clearly understood from the following description of preferred embodiments thereof, when taken in conjunction with the accompanying drawings. However, the embodiments and the drawings are given only for the purpose of illustration and explanation, and are not to be taken as limiting the scope of the present invention in any way whatsoever, which scope is to be determined by the appended claims. In the accompanying drawings, like reference numerals are used to denote like parts throughout the several views, and:

FIG. 1 is a block diagram showing a conceptual configuration of a voltage sensor and an information processing apparatus in a secondary battery degradation determination device according to one embodiment of the present invention;

FIG. 2 is an explanatory diagram showing a state where the voltage sensors are provided in parallel;

FIG. 3 is a circuit diagram showing the relationship in an emergency power supply including a plurality of batteries subjected to determination by the degradation determination device;

FIG. 4 is a flow chart showing signal transmission and reception among the voltage sensor, a controller, and a data server which form the degradation determination device;

FIG. 5A is a flow chart showing one example of a degradation determination process performed by the degradation determination device;

FIG. 5B is a flow chart showing one example of a degradation determination process performed by the degradation determination device;

FIG. 6 is a flow chart showing another example of the degradation determination process performed by the degradation determination device;

FIG. 7 is a flow chart showing still another example of the degradation determination process performed by the degradation determination device;

FIG. 8 is a flow chart showing still another example of the degradation determination process performed by the degradation determination device;

FIG. 9 is a flow chart showing still another example of the degradation determination process performed by the degradation determination device;

FIG. 10 is a flow chart showing still another example of the degradation determination process performed by the degradation determination device;

FIG. 11 is a flow chart showing still another example of the degradation determination process performed by the degradation determination device; and

FIG. 12 is a block diagram showing a conceptual configuration of a secondary battery degradation determination device according to another embodiment of the present invention.

### DESCRIPTION OF EMBODIMENTS

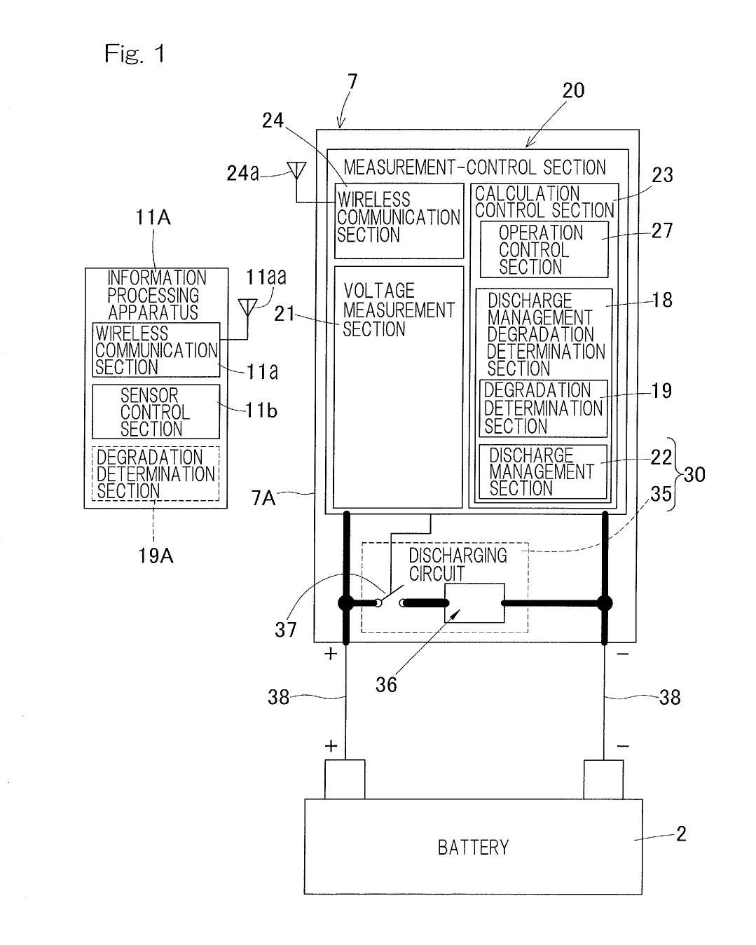

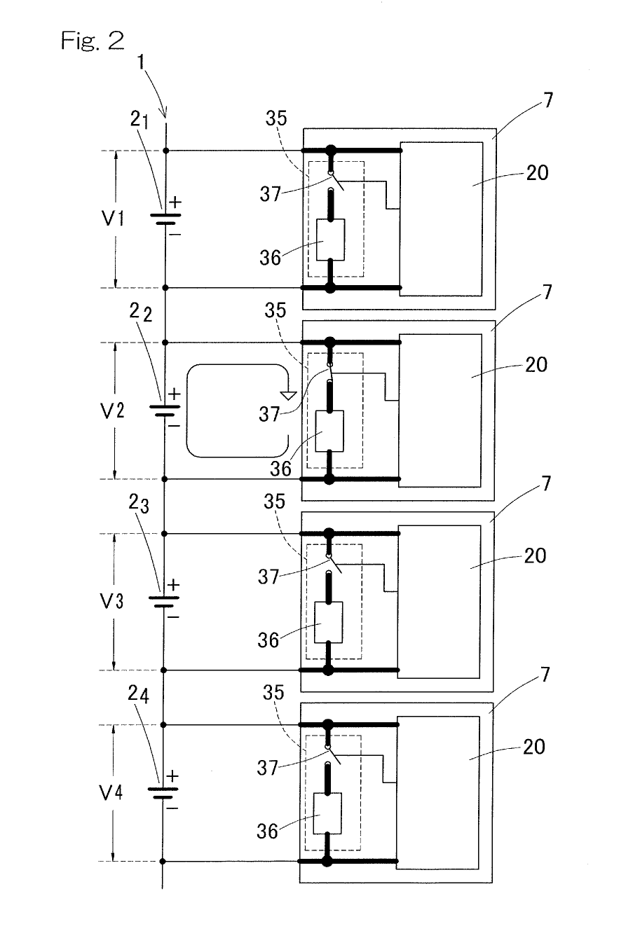

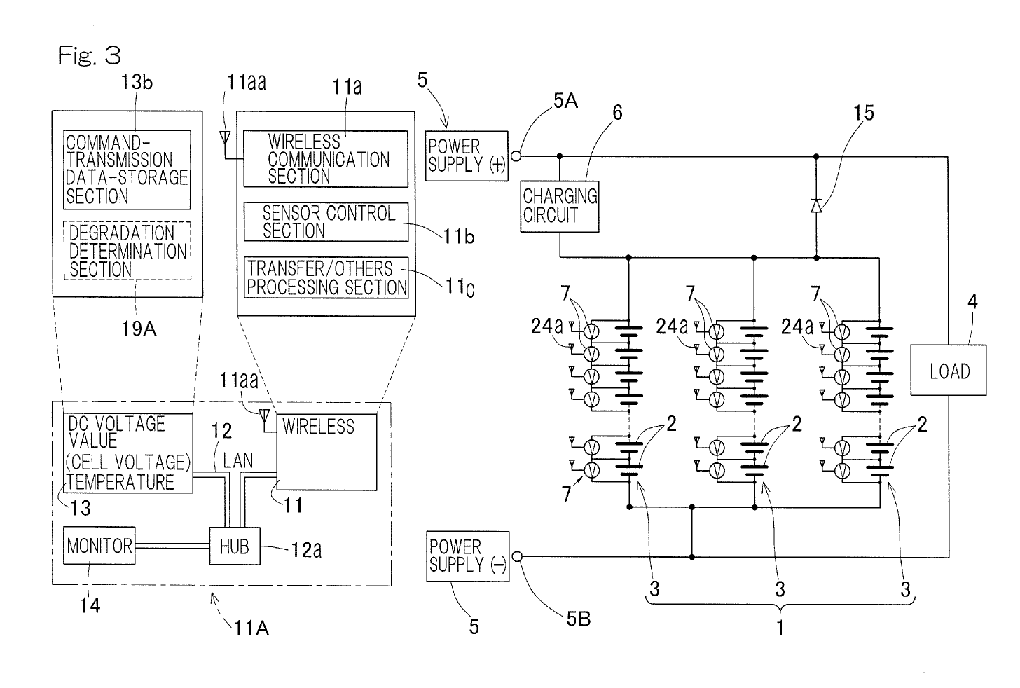

One embodiment of the present invention is described with reference to FIG. 1 to FIG. 5B. FIG. 1 is a conceptual diagram of a voltage sensor 7 and an information processing apparatus 11A which form this secondary battery degradation determination device. FIG. 3 shows an overall conceptual configuration of the degradation determination device and a circuit diagram of an emergency power supply provided with batteries subjected to determination.

In FIG. 3, a power supply 1 to be subjected to degradation determination is an emergency power supply in data centers, mobile phone base stations, or other various types of power supply devices for which stable electric power supply is required. The power supply 1 has a plurality of battery groups 3 each including a plurality of batteries 2 that are connected in series, each battery 2 being a secondary battery. These battery groups 3 are connected in parallel, and are connected to a load 4. Each battery 2 may be a battery that includes only one cell, or may be a battery in which a plurality of cells are connected in series. In this example, each battery 2 is implemented as one cell.

A main power supply 5 has positive and negative terminals 5A and 5B connected to the positive and negative terminals of the load 4. The emergency power supply 1 is connected via a charging circuit 6 and a diode 15 to the positive terminal 5A, and is directly connected to the negative terminal 5B, of the main power supply 5. The diode 15 is connected in parallel to the charging circuit 6 in the direction in which current is caused to flow from the emergency power supply 1 to the load 4. The main power supply 5 is implemented as a DC power supply or the like which is connected to, for example, a commercial AC power supply via a rectification circuit and a smoothing circuit (both not shown), and which converts AC power into DC power.

The positive potential of the emergency power supply 1 is lower than the positive potential of the main power supply 5, and does not normally cause current to flow to the load 4. However, when the main power supply 5 stops or the function thereof decreases, the potential at the main power supply 5 side decreases, and thus, feeding is performed via the diode 15 to the load 4 by use of electric charge stored in the emergency power supply 1. The charging type in which the charging circuit 6 is connected as described above is called a trickle charging type.

This secondary battery degradation determination device performs degradation determination on each individual battery 2 in the power supply 1, and includes a plurality of voltage sensors 7 connected to the respective batteries 2 and a single information processing apparatus 11A. In this example, the information processing apparatus 11A is composed of a controller 11 and a data server 13.

The voltage sensor 7 is described with reference to FIG. 1. Each voltage sensor 7 includes a measurement-control section 20 and a discharging circuit 35. The measurement-control section 20 is provided with: a voltage measurement section 21 which measures direct-current (DC) voltage between terminals of the battery 2; a calculation control section 23 implemented as a microcomputer or the like; and a wireless communication section 24.

The voltage measurement section 21 is the part, in the voltage sensor 7, that directly pertains to voltage measurement, or the part indispensable to voltage measurement, and is the part excluding additional configurations for voltage measurement. The voltage measurement section 21 is an instrument that is referred to as a voltage sensor in general. The voltage sensor 7 of the present embodiment may be referred to as a voltage sensor device, a voltage sensor unit, or the like.

The discharging circuit 35 is a series circuit of a current limiting resistor 36 and a switch 37. The current limiting resistor 36 is also referred to as a bleeder resistor. The switch 37 is implemented as a semiconductor switching element such as a transistor. The wireless communication section 24 is a means for performing wireless communication with the information processing apparatus 11A. The wireless communication section 24 transmits measured voltage, etc., and receives commands. The wireless communication section 24 has an antenna 24a.

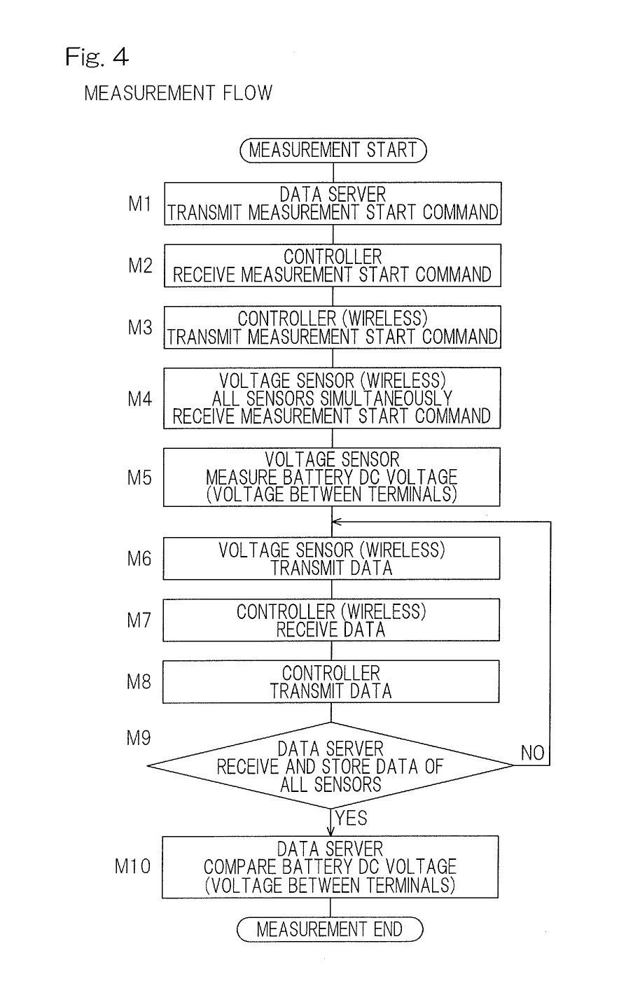

The calculation control section 23 is provided with an operation control section 27 and a discharge management degradation determination section 18. The operation control section 27 controls the entirety of the measurement-control section 20 and the wireless communication section 24, in accordance with a set sequence program and commands provided from the wireless communication section 24. Details of control of the operation control section 27 will be described later with reference to the flow chart shown in FIG. 4.

The discharge management degradation determination section 18 includes a discharge management section 22 which controls the discharging circuit 35 in accordance with voltage measured by the voltage measurement section 21. However, the discharge management degradation determination section 18 may include a degradation determination section 19 which determines degradation of the battery 2 on the basis of the discharge state brought by the discharge management section 22. When the data server 13 (FIG. 3) is provided, which voltage sensor 7 is outputting a degradation alert is managed in a centralized manner.

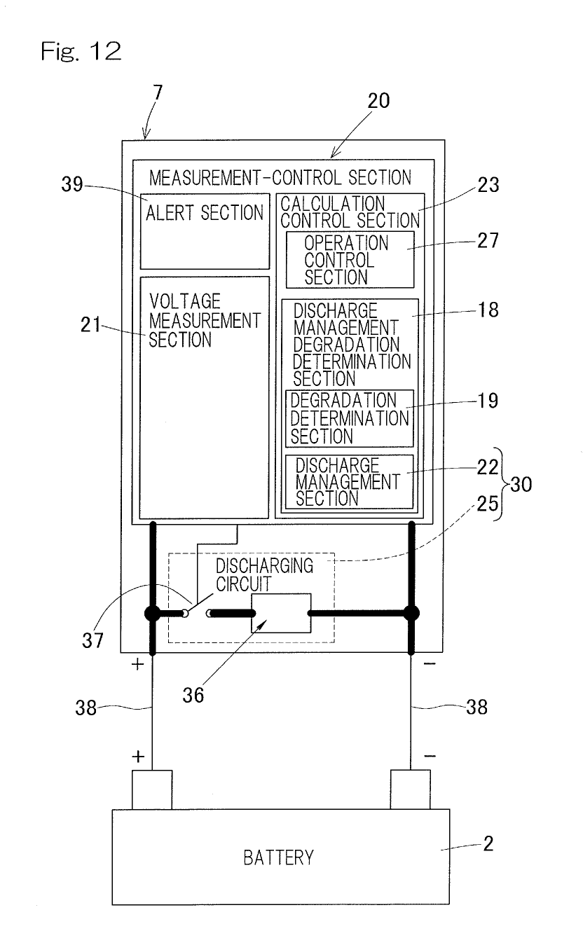

Depending on the system, there may be cases where no data server is provided. In such a case, as shown in FIG. 12, the voltage sensor 7 may be provided with the degradation determination section 19 and an alert section 39. The alert section 39 generates an alert, which is to be perceived by a surveillant, when the degradation determination section 19 has determined that the battery 2 has been degraded. The alert section 39 may generate light, sound, or both light and sound. As a specific example of the alert section 39, a light emitting diode (LED), a speaker, a device that generates an image of letters, symbols, etc., on a screen of a liquid crystal display device, or the like can be used. In this case, the voltage sensor 7 does not include the wireless communication section. All of the components of the voltage sensor 7, including the alert section 39, may be housed in a common housing (not shown). In this configuration, the voltage sensor 7 can, by itself, perform degradation determination and issue an alert. The degradation determination section 19 may be configured to determine degradation, using a threshold set in advance as a reference. The voltage sensor 7 and other components shown in FIG. 12 are the same as those of a first embodiment described with reference to FIG. 1 to FIG. 5B, etc.

More specifically, in FIG. 1, the discharge management section 22 monitors battery DC voltage measured by the voltage measurement section 21. Then, the discharge management section 22 turns on the switch 37 to discharge the battery 2 when the battery DC voltage is higher than a set upper limit value, monitors the battery DC voltage while the switch 37 is on, and turns off the switch 37 to stop the discharge when the battery DC voltage has become lower than a set lower limit value. The “upper limit value” and the “lower limit value” are values that are determined as desired, but are respectively set, for example, to the upper limit or the lower limit of the range of normal voltage which is the voltage in the case where degradation of the battery 2 has not occurred.

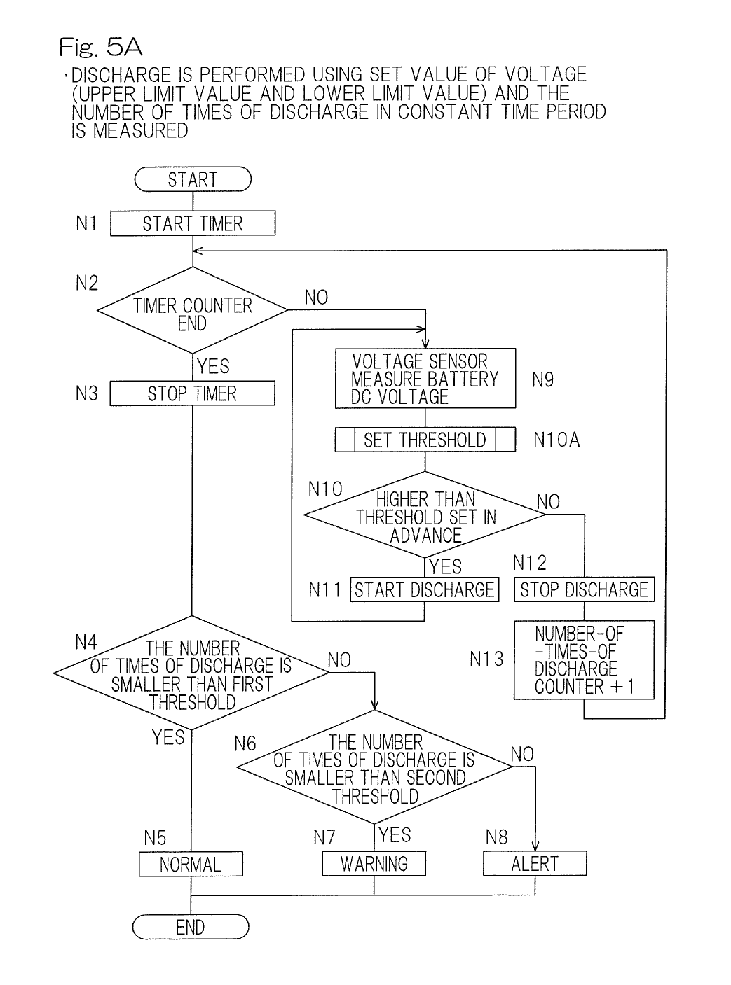

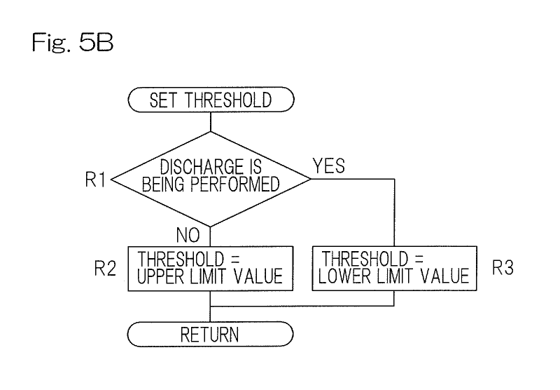

The degradation determination section 19 has a function of setting a discharge condition, such as a threshold, to the discharge management section 22 for performing degradation determination, and a function of controlling the discharge management section 22. Instead of providing the degradation determination section 19 in the voltage sensor 7, the degradation determination section 19A may be provided in the information processing apparatus 11A which is provided separately from the voltage sensor 7, as described above. Still alternatively, portions of the degradation determination section may be shared by both the voltage sensor 7 and the information processing apparatus 11A. More specifically, the degradation determination section 19, 19A has the functions indicated in the flow charts shown in FIG. 5A to FIG. 11. For example, the degradation determination section 19, 19A are provided with the timers, etc., indicated in the flow charts.

Examples of various types of processes performed by the degradation determination section 19 are shown in the flow charts in FIG. 5A to FIG. 11. Although details of the examples shown in FIG. 5A to FIG. 11 will be described later, in each drawing, the steps of starting and stopping discharge on the basis of comparison of a measurement value of battery DC voltage with a threshold correspond to the discharge management section 22, and the other steps correspond to the degradation determination section 19 (19A). FIG. 5A to FIG. 11 include contents of processes performed by the discharge management section 22, and are examples of programs performed by the discharge management degradation determination section 18, for example, and the programs thereof may be implemented as one sequence program.

With reference to FIG. 1, a hardware configuration example of the voltage sensor 7 is described. The measurement-control section 20 and the discharging circuit 35 are mounted on a common circuit board 7A. Thus, the current limiting resistor 36, the switch 37, and the voltage measurement section 21 are mounted on a common circuit board. Although the measurement-control section 20 is driven by electric power of the battery 2 subjected to degradation determination, the circuit that feeds the measurement-control section 20 from the battery 2 and the circuit that forms the discharging circuit 35 share the positive and negative cables 38. Therefore, the circuit that connects the current limiting resistor 36 and the switch 37 to the battery 2 and the circuit that connects the voltage measurement section 21 to the battery 2 share the positive and negative cables 38. Although not shown, each voltage sensor 7 may include a temperature sensor in addition to the voltage measurement section 21.

In FIG. 1, the information processing apparatus 11A includes: a wireless communication section 11a which performs wireless communication with respect to the wireless communication section 24 of each voltage sensor 7; and a sensor control section 11b which controls each voltage sensor 7. The wireless communication section 11a has an antenna 11aa. As described above, there are cases where the degradation determination section 19A is provided or not provided in the information processing apparatus 11A.

Specifically, the information processing apparatus 11A is formed by the controller 11, the data server 13, and a monitor 14 as shown in FIG. 3. The controller 11 is provided with: the wireless communication section 11a which performs wireless communication with each voltage sensor 7; and the sensor control section 11b. The data server 13 is provided with the degradation determination section 19A. The controller 11 and the data server 13 are mutually connected via a communication network 12. The communication network 12 is implemented as a LAN such as a wireless LAN, and has a hub 12a. The communication network 12 may be a wide area network. The data server 13 can communicate with information processing apparatuses (not shown) such as personal computers at remote places through the communication network 12 or other communication networks, and data can be monitored from any place. Preferably, communication between the controller 11 and the data server 13 are assured through handshake.

The controller 11 mainly performs control of each voltage sensor 7 and includes a transfer or the like processing section 11c which performs communication with the data server 13 and processing of commands transmitted from the data server 13, in addition to the wireless communication section 11a and the sensor control section 11b. The data server 13 includes a command-transmission data-storage section 13b which generates and transmits commands and which stores reception data, in addition to the degradation determination section 19A.

Operation performed in the configuration mentioned above is described. Examples of details of the functions of the components are shown in the below-mentioned flow charts. FIG. 4 shows operation of controlling the voltage sensor 7 performed by the data server 13 (FIG. 3) and the controller 11. The data server 13 transmits a measurement start command from the command-transmission data-storage section 13b through the communication network 12 (step M1). The controller 11 receives the measurement start command (step M2) and wirelessly transmits the measurement start command (step M3).

Each voltage sensor 7 simultaneously receives the wirelessly transmitted measurement start command (step M4), and each voltage sensor 7 measures DC voltage between the terminals of the battery (step M5). Each voltage sensor 7 wirelessly transmits data such as measured battery DC voltage (including a temperature measurement value when a temperature sensor is provided) (step M6).

The controller 11 wirelessly receives the transmitted data such as the battery DC voltage (step M7), and transmits the received data through the communication network 12 (step M8). The data server 13 receives the transmitted data such as the battery DC voltage, and stores the data in the command-transmission data-storage section 13b (step M9). The processes of steps M6 to M9 are sequentially repeated in the voltage sensors 7 (NO in step M9 causes the repetition). When the reception and storage of data from all the voltage sensors 7 have ended, the data server 13 compares the battery DC voltage with a set value, and performs degradation determination (step M10). It should be noted that FIG. 4 shows an example in which the degradation determination section 19A is provided in the data server 13 and this degradation determination section 19A performs degradation determination, and each voltage sensor 7 performs a role of transmitting measured battery DC voltage.

One example of degradation determination is described with reference to FIG. 5A and FIG. 5B. Generally, FIG. 5A and FIG. 5B show an example in which the frequency of discharge is determined on the basis of the number of times of discharge, thereby performing degradation determination, wherein discharge is started and stopped on the basis of set values of voltage (upper limit value and lower limit value), and the number of times of discharge in a constant time period is counted.

First, a timer (not shown) is started (step N1), and whether the count of the timer has reached a set time period (which is set in terms of the number of times) is determined (step N2). Until the set time period is reached (NO in step N2), the voltage measurement section 21 of the voltage sensor 7 measures the battery DC voltage (step N9), and after step N10A described later, the discharge management section 22 determines whether the battery DC voltage is higher than the set value of voltage (threshold set in advance) (step N10). It should be noted that when the battery DC voltage is monitored, discharge may be stopped by temporarily turning off the switch 37 (not shown).

In this case, as the threshold, an upper limit value and a lower limit value are predetermined in advance before practical use, and in step N10A in which a threshold is set, as shown in FIG. 5B, the “upper limit value” is selected and set when discharge is not being performed (NO in step R1) and the “lower limit value” is selected and set when discharge is being performed (YES in step R1). The “upper limit value” and the “lower limit value” are values that are predetermined as desired, and are respectively set to, for example, the upper limit and the lower limit of the range of normal voltage in which range degradation of the battery 2 has not occurred. For example, in a case of a battery implemented as one cell of 2 V, if the upper limit value is set to 2.23 V, or is set to about 2.23 to 2.4 V in consideration of voltage increase due to internal resistance and charge current, battery 2 that has been degraded can be discriminated. The lower limit value is not less than 1.8 V. When the average value of the DC voltages of the batteries is known, the lower limit value is set to the average value. The lower limit value is set such that battery that has a high voltage through relative comparison is forcibly discharged so as to attain a uniform DC voltage. If voltage between terminals of a battery group in which a plurality of batteries are connected in series (the main power supply 5) is known, voltage obtained by dividing the voltage between terminals of the main power supply 5 by the number of batteries connected in series may be used as a reference. This also applies to the examples in the drawings mentioned below.

In step N10, at the beginning, discharge is not being performed, and the threshold is the “upper limit value”, and when the battery DC voltage is higher than the “upper limit value” which is the threshold (YES in step N10), discharge is started by the switch 37 being turned on (step N11), and process from measurement of battery DC voltage (step N9) to comparison with the threshold (step N10) are repeated again. During this repetition, the “threshold” is the “lower limit value” (FIG. 5B). When the battery DC voltage is not higher than the lower limit value (NO in step N10), the discharge is stopped (step N12), and a number-of-times-of-discharge counter (not shown) of the discharge management section 22 is incremented by 1 (step N13). Then, the process returns to step N2.

When the count of the timer has reached the set time period in step N2, the timer is stopped (step N3). Then, the degradation determination section 19 (19A) compares the number of times of discharge counted by the number-of-times-of-discharge counter with a first threshold which is a first set number of times (step N4). When the number of times of discharge is smaller than the first threshold (YES in step N4), the degradation determination section 19A determines that the battery 2 is normal (step N5).

When the degradation determination section 19 (19A) compares the number of times of discharge counted by the number-of-times-of-discharge counter with the first threshold which is the first set number of times (step N4) and the number of times of discharge is not smaller than the first threshold (NO in step N4), the degradation determination section 19 (19A) compares the number of times of discharge with a second threshold (step N6). When the number of times of discharge is smaller than the second threshold (YES in step N6), the degradation determination section 19A determines that moderate degradation has occurred and causes a warning to be issued (step N7). When the number of times of discharge counted by the number-of-times-of-discharge counter is not smaller than the second threshold (NO in step N6), the degradation determination section 19A determines that severe degradation has occurred and causes an alert, which is a stronger warning than the above-mentioned warning, to be issued (step N8). In this manner, degradation determination is performed on the basis of the number of times of discharge.

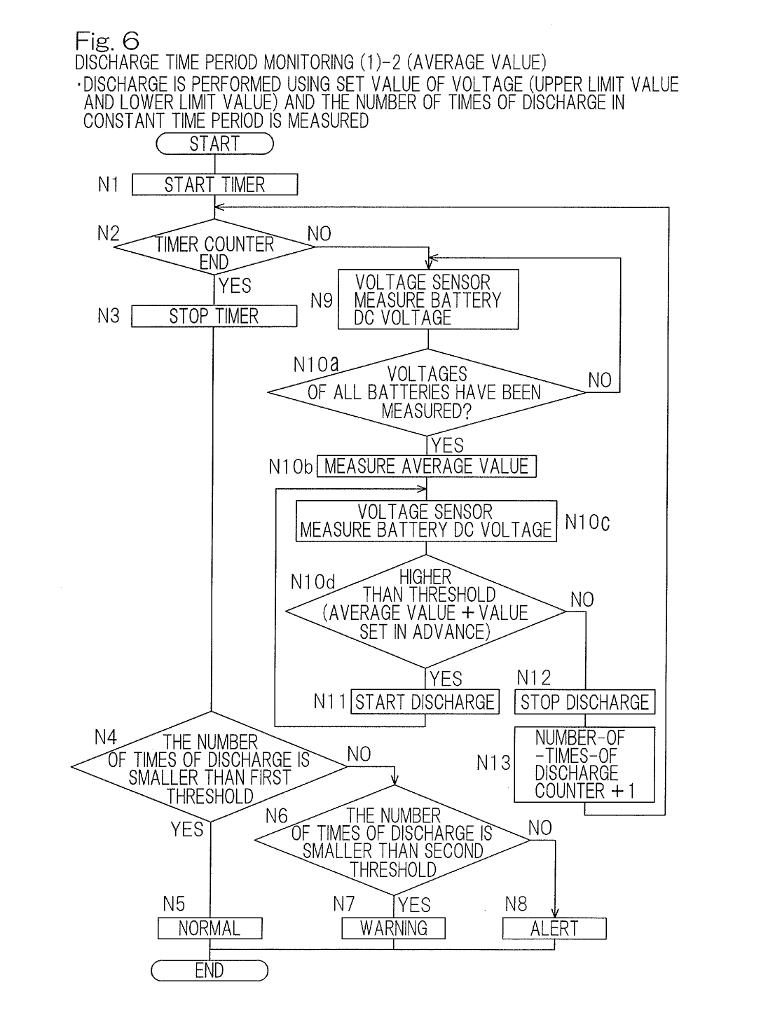

FIG. 6 shows an example in which, in the processes shown in FIG. 5A and FIG. 5B, the threshold for performing discharge is determined, using the average value of battery DC voltages of the batteries 2 as a reference. The other processes are the same as those in the examples shown in FIG. 5A and FIG. 5B, and the steps in which the same processes as those in the examples shown in FIG. 5A and FIG. 5B are performed are denoted by the same step numbers used therein.

In this example, after measurement of battery DC voltage performed by the voltage sensor 7 (step N9), it is determined whether voltages of all the target batteries 2 of the power supply 1 have been measured (step N10a), and until voltages of all the batteries 2 have been measured, battery 2 voltage measurement is performed. Each measured battery DC voltage is stored in a predetermined storage region. When voltages of all the batteries 2 have been measured (YES in step N10a), the average value of the battery DC voltages is calculated (step N10b). Although not shown in FIG. 6, values obtained by respectively adding, to this average value, an addition value and a subtraction value set in advance are set as thresholds which are the upper limit value and the lower limit value.

Then, the measured battery DC voltage of each battery 2 is compared with the threshold (step N10d). Although not shown, before this comparison, as described with reference to FIG. 5B, the threshold is set to the upper limit value when discharge is not being performed, and the threshold is set to the lower limit value when discharge is being performed. When the measured battery DC voltage of the battery 2 is compared with the threshold and the measured battery DC voltage of the battery 2 is higher than the upper limit value (YES in step N10d), discharge is started (step N11). Then, measurement of battery DC voltage (step N10c) and comparison with the threshold (step N10d. Also in step O2d described later, comparison with a threshold is performed) are repeated. During the repetition, since discharge is being performed in step N10d, the battery DC voltage is compared with the lower limit value, and when the battery DC voltage is not higher than the lower limit value, the discharge is stopped (step N12).

The other processes are the same as those in the examples shown in FIG. 5A and FIG. 5B, and thus, redundant description is omitted. Since the upper limit value and the lower limit value of voltage for discharge and discharge stop are determined using the average value as a reference in this manner, it is possible to cause each individual power supply to perform more appropriate discharge, thereby increasing the degradation determination accuracy.

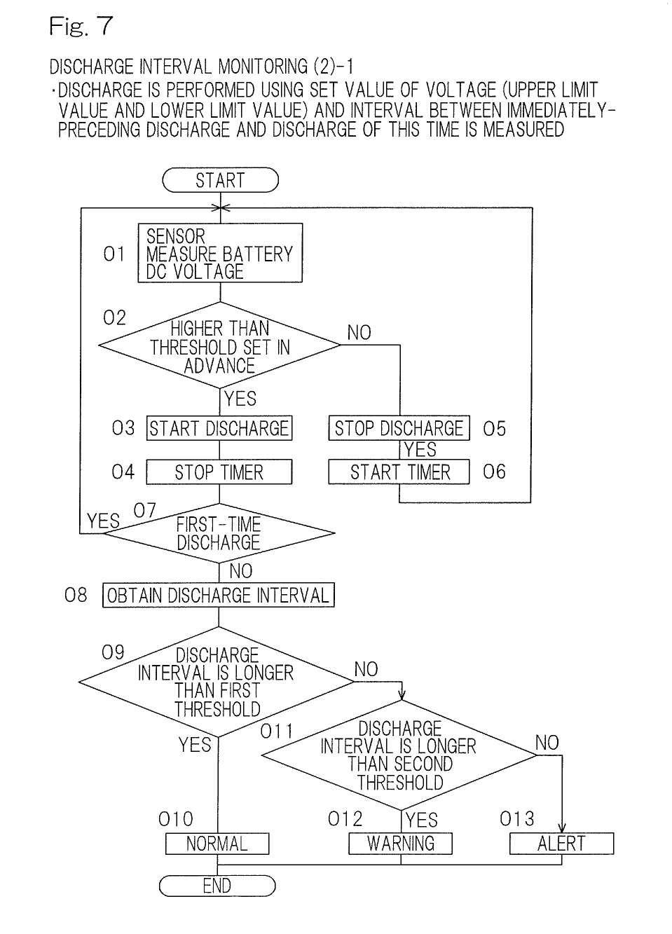

FIG. 7 shows a first example in which degradation determination based on the discharge frequency is performed on the basis of the time period of discharge interval. Here, the time period from a discharge end to the next discharge start is compared. First, battery DC voltage is measured by the voltage sensor 7 (step O1), and it is determined whether the voltage is higher than a threshold set in advance, which is a set value of voltage (step O2).

In this case, before step O2, an upper limit value and a lower limit value are predetermined as the threshold, and, as described with reference to FIG. 5B, the “upper limit value” is selected and set when discharge is not being performed, and the “lower limit value” is selected and set when discharge is being performed. Since discharge is not being performed at the beginning, the threshold is the upper limit value. When the battery DC voltage is not higher than the upper limit value (NO in step O2), discharge is stopped (when discharge has been stopped, the stopped state is maintained) (step O5), and a step of starting a timer (step O6) is performed (the timer is not shown). In step O6, the timer is started in the first loop which starts immediately after the state has changed from the charging state when “charge is being performed”. Therefore, the timer is not started this time. Then, the process returns to the battery DC voltage measurement process (step O1).

In the next determination process (step O2), since the discharge has been stopped, the battery DC voltage is compared with the upper limit value, and when the battery DC voltage is higher than the upper limit value (YES in step O2), discharge is started (step O3), and the timer is stopped (step O4). However, when the timer has been stopped, the stopped state is maintained. In the next determination process as to whether the discharge is the first-time discharge (step O7), since the discharge is the first-time discharge at the present (YES in step O7), the process returns to the battery DC voltage measurement process (step O1). In the present embodiment, with respect to the determination as to whether the discharge is the first-time discharge (step O7), a “flag indicating that discharge is being performed” (not shown) is set to “0” after the activation, the “flag indicating that discharge is being performed” is set to “1” during discharge, and the “flag indicating that discharge is being performed” is set to “2” after the discharge ends (charge is being performed). Thereafter, when the “flag indicating that discharge is being performed” is “2”, this value of “2” is maintained. When the “flag indicating that discharge is being performed” is “1”, the process returns to step O1. This also applies to the flowcharts in other drawings for simplification thereof.

In the next determination process (step O2), since discharge is being performed, the battery DC voltage is compared with the lower limit value. When the battery DC voltage has become lower than the lower limit value, the discharge is stopped (step O5) (end of discharge), and the timer is started (step O6). Then, the process returns to the battery DC voltage measurement process (step O1). In the next determination process (step O2), since discharge has been stopped, the battery DC voltage is compared with the upper limit value. When the battery DC voltage is higher than the upper limit value (YES in step O2), discharge is started (step O3) (next discharge is started), and the timer is stopped (step O4).

In the next determination as to whether the discharge is the first-time discharge (step O7), since the discharge at the present time is not the first-time discharge (NO in step O7), the process proceeds to step O8, and the time period counted by the timer, i.e., the time period from the discharge end to the next discharge start, is obtained as a discharge interval.

It is determined whether this discharge interval is longer than a first threshold which is a set value of the interval (step O9). When the discharge interval is longer than the first threshold, it is determined that the battery 2 is normal (step O10). When the discharge interval is not longer than the first threshold, the discharge interval is compared with a second threshold (step O11). When the discharge interval is longer than the second threshold, it is determined that moderate degradation has occurred, and a warning is issued (step O12). When the discharge interval is not longer than the second threshold, it is determined that severe degradation has occurred, and an alert which is a stronger warning than the above-mentioned warning, is issued (step O13). Also when the determination is performed on the basis of the discharge interval in this manner, battery degradation can be determined in a simple manner. If the discharge interval is short, it is possible to determine that the battery 2 has degraded.

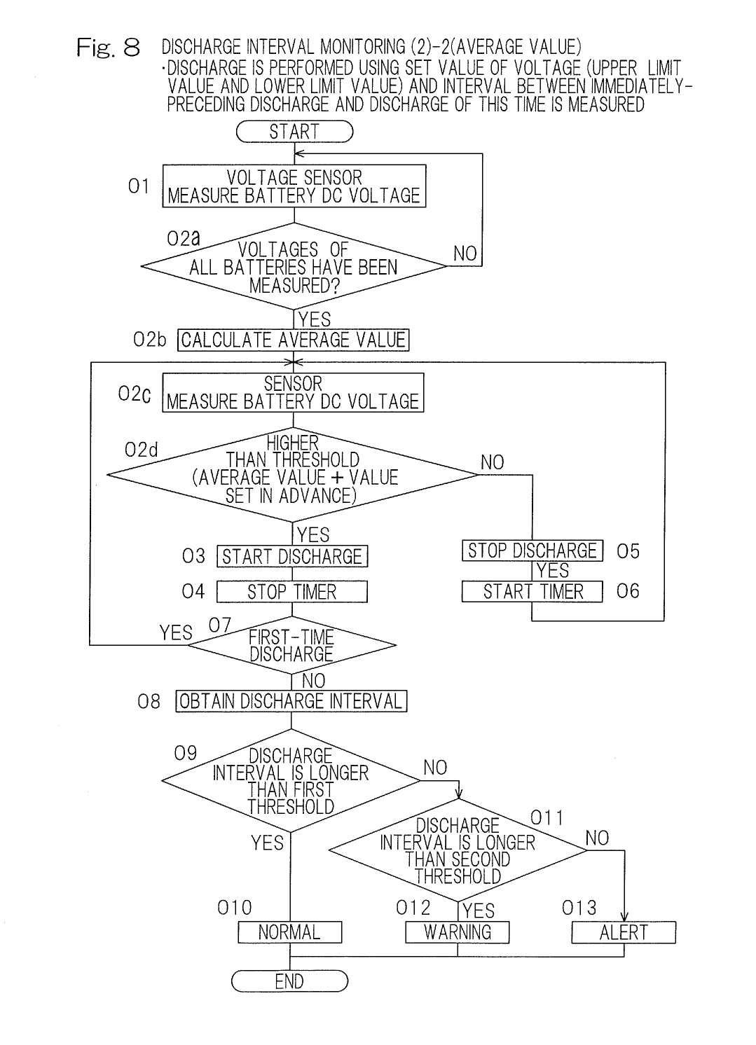

FIG. 8 shows an example in which, in the example shown in FIG. 7, the threshold for performing discharge is predetermined, using the average value of battery DC voltages of the batteries 2 as a reference, as in the example shown in FIG. 6. The other processes are the same as those in the example shown in FIG. 7, and the steps in which the same processes as those in the example shown in FIG. 7 are performed are denoted by the same step numbers used therein.

In this example, after measurement of battery DC voltage performed by the voltage sensor 7 (step O1), it is determined whether voltages of all the target batteries 2 of the power supply 1 have been measured (step O2a), and until voltages of all the batteries 2 have been measured, battery 2 voltage measurement is performed. Each measured battery DC voltage is stored in a predetermined storage region. When voltages of all the batteries 2 have been measured, the average value of the battery DC voltages is calculated (step O2b). Values obtained by respectively adding, to this average value, an addition value and a subtraction value set in advance are determined as the upper limit value and the lower limit value. The other processes are the same as those in the example shown in FIG. 7, and thus, redundant description is omitted.

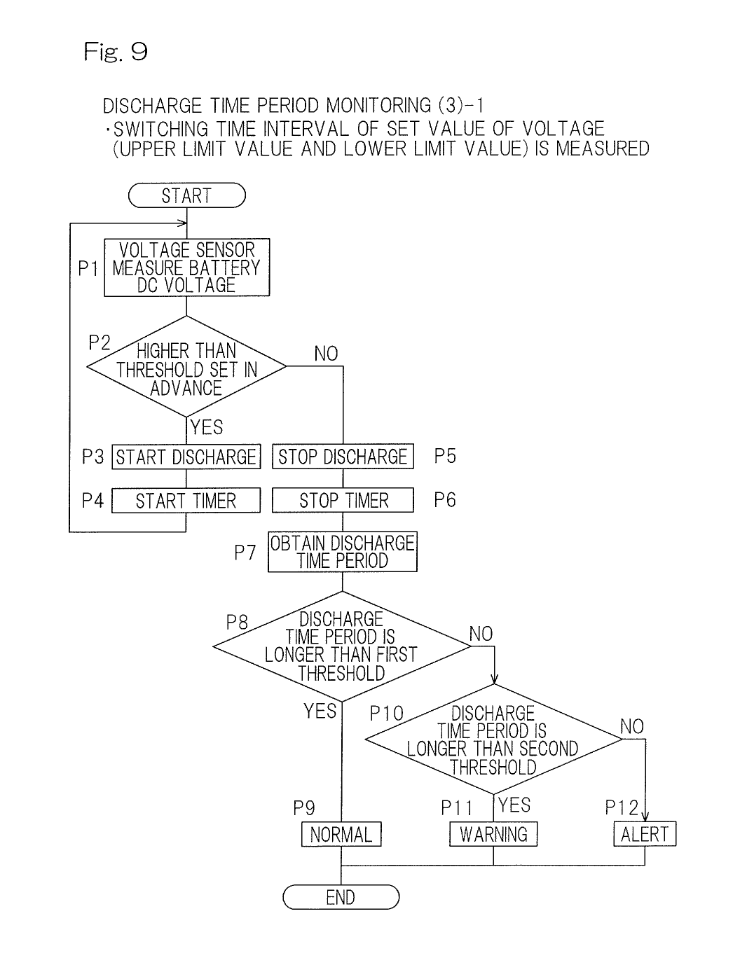

FIG. 9 shows an example in which the switching time interval in which discharge start and discharge stop are switched on the basis of two set values of voltage (upper limit value and lower limit value) is measured, and discharge frequency is determined. Battery DC voltage is measured by the voltage sensor 7 (step P1), and it is determined whether the battery DC voltage is higher than a threshold which is set in advance and which is a set value of voltage (step P2). In this case, an upper limit value and a lower limit value are determined as the threshold in advance at the time of designing, and before step P2, as described with reference to FIG. 5B, the “upper limit value” is selected and set when discharge is not being performed, and the “lower limit value” is selected and set when discharge is being performed. When the battery DC voltage is higher than the upper limit value in the determination performed in step P2 (YES in step P2), discharge is started (step P3), a timer (not shown) is started (step P4), and then, the process returns to step P1. It should be noted that, in the step P4 of starting the timer, the timer is not re-started in each loop process, but the timer is started in the first loop which starts immediately after the state has changed from the discharging state when “discharge is being performed”.

After the measurement of battery DC voltage (step P1), in the determination process in step P2, when the battery DC voltage is not higher than the threshold (lower limit value) (NO in step P2), the discharge is stopped (step P5), and the timer is stopped (step P6). Then, the discharge time period, which is the time period measured by the timer, is obtained (step P7). It is determined whether the obtained discharge time period is longer than a first threshold which is a set value of the time period (step P8). When the obtained discharge time period is longer than the first threshold (YES in step P8), it is determined that the battery 2 is normal (step P9). When the obtained discharge time period is not longer than the first threshold which is a set value of the time period (NO in step P8), the discharge time period is compared with a second threshold (step P10). When the obtained discharge time period is longer than the second threshold (YES in step P10), it is determined that moderate degradation has occurred, and a warning is issued (step P11). When the discharge time period is not longer than the second threshold (NO in step P10), it is determined that severe degradation has occurred, and an alert, which is a stronger warning than the above-mentioned warning, is issued (step P12).

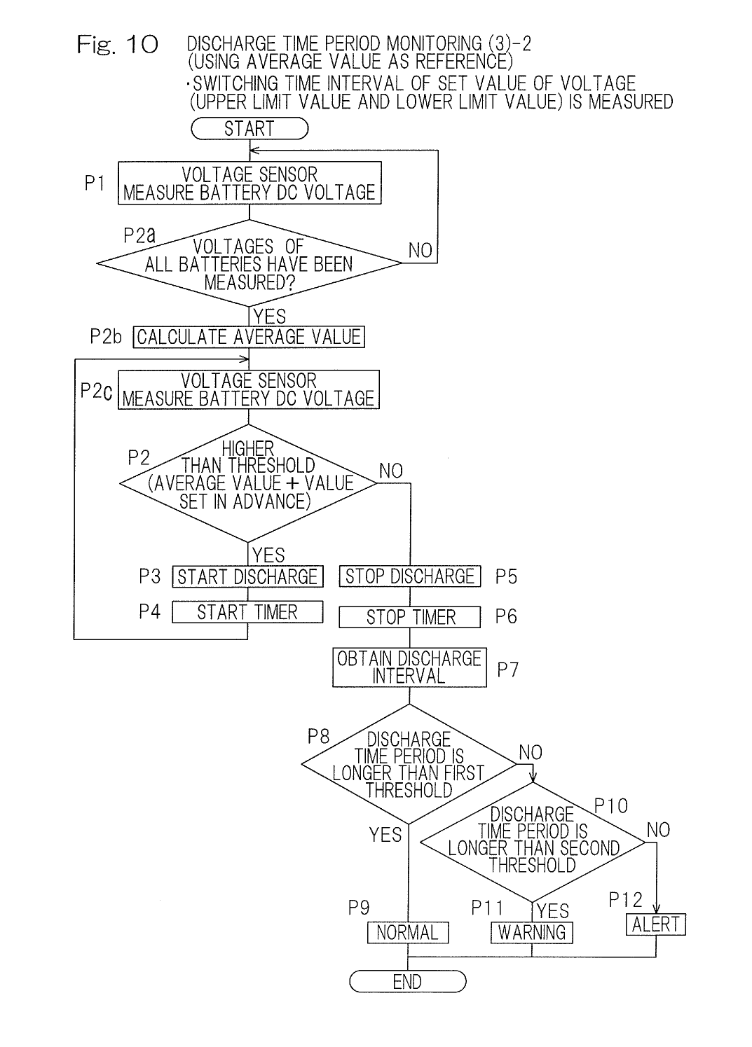

FIG. 10 shows an example in which, in the example shown in FIG. 9, the threshold for performing discharge is predetermined, using the average value of battery DC voltages of the batteries 2 as a reference, as in the examples shown in FIG. 6 and FIG. 8. The other processes are the same as those in the example shown in FIG. 9, and the steps in which the same processes as those in the example shown in FIG. 9 are performed are denoted by the same step numbers used therein.

In this example, after measurement of battery DC voltage performed by the voltage sensor 7 (step P1), it is determined whether voltages of all the target batteries 2 of the power supply 1 have been measured (step P2a), and until voltages of all the batteries 2 have been measured, battery 2 voltage measurement is performed. Each measured battery DC voltage is stored in a predetermined storage region. When voltages of all the batteries 2 have been measured, the average value of the battery DC voltages is calculated (step P2b). Values obtained by adding, to this average value, an addition value set in advance is used as a threshold, and the measured battery DC voltage of each battery 2 is compared with the threshold (step P2). Thereafter, the processes are performed in a manner similar to that in the example shown in FIG. 9.

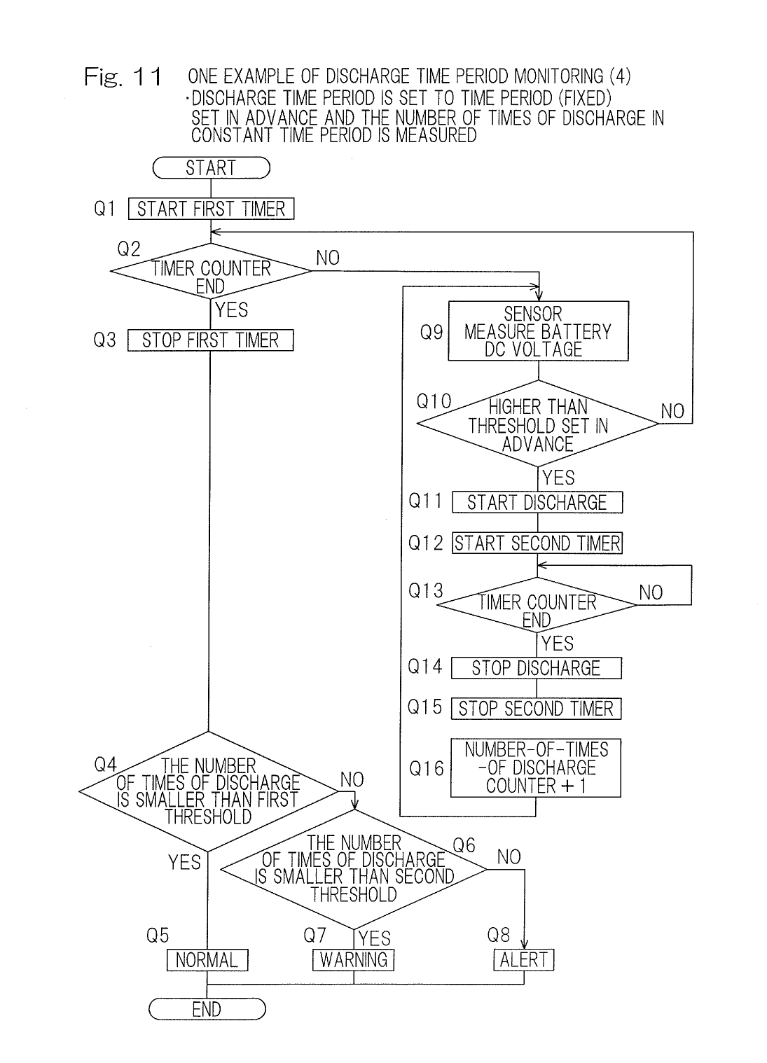

FIG. 11 shows an example in which the number of times of discharge is counted within a constant time period. First, a first timer (not shown) is started (step Q1), and it is determined whether the timer has reached a set time period (the time is counted in terms of the count number) (step Q2). When the set time period has not been reached (NO in step Q2), battery DC voltage is measured by the voltage sensor 7 (step Q9), and it is determined whether the battery DC voltage is higher than a threshold which is set in advance and which is a set value of voltage (step Q10). In this case, an upper limit value and a lower limit value are predetermined as the threshold in advance at the time of designing, and before step Q10, as in the example described with reference to FIG. 5B, the “upper limit value” is selected and set when discharge is not being performed, and the “lower limit value” is selected and set when discharge is being performed.

When the battery DC voltage measured by the voltage sensor 7 is higher than the threshold (YES in step Q10), discharge is started (step Q11), and a second timer (not shown), which is a timer for counting the discharge time period, is started (step Q12). It is determined whether the count of the second timer (not shown) has reached a set time period (step Q13). When the count of the second timer has reached the set time period, the discharge is stopped (step Q14), the second timer (not shown) is stopped (step Q15), and the number-of-times-of-discharge counter is incremented by 1 (step Q16). Then, the process returns to step Q9, and the processes of steps Q9 to Q16 are repeated. In the determination in step Q10, the threshold is the lower limit value.

During this time, the time is being counted by the first timer. When the count of the first timer has reached a set time period (YES in step Q2), the first timer is stopped (step Q3), and it is determined whether the number of times of discharge is smaller than a first threshold which is a set value of the number of times (step Q4). When the number of times of discharge is smaller than the first threshold (YES in step Q4), it is determined that the battery 2 is normal (step Q5). When the number of times of discharge is not smaller than the first threshold (NO in step Q4), it is determined whether the number of times of discharge is smaller than a second threshold (step Q6). When the number of times of discharge is smaller than the second threshold (YES in step Q6), it is determined that moderate degradation has occurred and a warning is issued (step Q7). When the number of times of discharge is not smaller than the second threshold (NO in step Q6), an alert, which is a stronger warning than the above-mentioned warning, is outputted (step Q8).

In this secondary battery degradation determination device, degradation determination is performed as in the examples described above, whereby the advantages below are obtained. When a battery 2 is degraded, internal resistance increases, and thus, if DC voltage of each individual battery 2 is measured, degradation of each battery 2 can be determined to some extent. However, variation in battery DC voltage is also caused by other factors, and thus, degradation of the battery cannot be accurately determined when done only through measurement of the voltage between terminals.

However, in this degradation determination device, when battery DC voltage is high, energy is consumed by the current limiting resistor 36 through discharge, the battery DC voltage is measured again, and degradation is determined on the basis of the discharge frequency. Therefore, influence of variation in battery DC voltage due to factors other than degradation is reduced, and thus, degradation of the battery can be determined accurately to some extent. In addition, since no means for applying measurement current to the battery 2 is required, the device has a simple configuration. Accordingly, in a simple configuration, degradation of a secondary battery can be determined accurately to some extent. Therefore, this degradation determination device is suitable for degradation prevention in an emergency power supply in which a large number, i.e., tens and hundreds, of batteries 2 are connected. Furthermore, since discharge is performed when battery DC voltage is high, an advantage that overcharge of a degraded battery is prevented and thus prevention of acceleration of degradation is also obtained.

In addition, for example, in a case where the degradation determination section 19, 19A performs determination based on the number of times of discharge as a process of degradation determination based on the discharge frequency, degradation of the battery 2 can be determined in a simple manner. Also in a case where the degradation determination section 19, 19A measures a discharge interval and performs determination based on the discharge interval as the degradation determination based on the discharge frequency, degradation of the battery can be determined in a simple manner.

In this degradation determination device, discharge is performed with energy being consumed by the current limiting resistor 36 as described above, and thus, sudden discharge is inhibited. Since the switch 37 is temporarily turned off at a constant interval after discharge is started, battery DC voltage during discharge can be measured. Then, since voltage measurement and comparison with a set value are repeated and the discharge interval is compared with a set interval, degradation of the battery can be accurately determined.

The “set value of voltage” may be a fixed value, but there are cases where appropriate battery DC voltage slightly differs depending on the individual power supply. Therefore, if the average value of battery DC voltages of all the batteries is obtained as described above and a set value of voltage for performing discharge is determined using this average value as a reference, it is possible to cause each individual power supply to perform more appropriate discharge, thereby increasing the degradation determination accuracy.

As described above, when the current limiting resistor 36 and the switch 37 are mounted on the same circuit board 7A as that of the voltage measurement section 21, the device is simplified and made compact. In a case where the circuit of the current limiting resistor 36 and the switch 37 and the circuit of the voltage measurement section 21 share the cable connected to the battery, cable wiring is simplified.

Each of the degradation determination devices in the embodiments described above includes: a plurality of voltage sensors 7 each including the voltage measurement section 21, the discharging circuit 35, and the discharge management section 22; and a single information processing apparatus 11A provided for these voltage sensors 7 and including the degradation determination section 19 (19A). Therefore, in order to perform degradation determination of each battery in an emergency power supply in which a large number, i.e., tens and hundreds, of batteries are connected, it is sufficient to use a single information processing apparatus, and thus, the configuration is simplified.

Although the present invention has been fully described in connection with the preferred embodiments thereof with reference to the accompanying drawings which are used only for the purpose of illustration, those skilled in the art will readily conceive numerous changes and modifications within the framework of obviousness upon the reading of the specification herein presented of the present invention. Accordingly, such changes and modifications are, unless they depart from the scope of the present invention as delivered from the claims annexed hereto, to be construed as included therein.

### REFERENCE NUMERALS

1 . . . power supply
2 . . . battery
3 . . . battery group
4 . . . load
5 . . . main power supply
5A, 5B . . . terminal
6 . . . charging circuit
7 . . . voltage sensor
7A . . . circuit board
11 . . . controller
11A . . . information processing apparatus
11a . . . wireless communication section
11b . . . sensor control section
11c . . . transfer or the like processing section
12 . . . communication network
13 . . . data server
13b . . . command-transmission data-storage section
14 . . . monitor
15 . . . diode
18 . . . discharge management degradation determination section
19 . . . degradation determination section
19A . . . degradation determination section
20 . . . measurement-control section
21 . . . voltage measurement section
22 . . . discharge management section
23 . . . calculation control section
24 . . . wireless communication section
25 . . . AC voltage measurement section
27 . . . operation control section
30 . . . discharge section
32 . . . discharge processing section
35 . . . discharging circuit
36 . . . current limiting resistor
37 . . . switch
38 . . . cable
39 . . . alert section

What is claimed is:

1. A secondary battery degradation determination device comprising:
a voltage measurement section configured to measure DC voltage between terminals of a battery which is a secondary battery;
a discharging circuit which is a series circuit of a current limiting resistor and a switch and connected in parallel to the battery;
a discharge management section configured to
monitor battery DC voltage measured by the voltage measurement section,
turn on the switch to discharge the battery when the battery DC voltage is higher than a set upper limit value,
monitor the battery DC voltage while the switch is on, and
turn off the switch to stop the discharge when the battery DC voltage has become lower than a set lower limit value; and
a degradation determination section configured to measure a discharge frequency in the discharging circuit caused as a result of control by the discharge management section, and determine degradation of the battery on the basis of the discharge frequency.

2. The secondary battery degradation determination device as claimed in claim 1, wherein
as a process of degradation determination based on the discharge frequency, the degradation determination section measures the number of times of discharge performed in a set time period, and determines that the battery has been degraded when the number of times of discharge is greater than a set number of times.

3. The secondary battery degradation determination device as claimed in claim 1, wherein
as degradation determination based on the discharge frequency, the degradation determination section measures a discharge interval between immediately-preceding discharge and discharge at the present time, and determines that the battery has been degraded when the discharge interval is shorter than a set interval.

4. The secondary battery degradation determination device as claimed in claim 1, wherein
as degradation determination based on the discharge frequency, the degradation determination section measures a switching time period which is a time period between start of the discharge and stop of the discharge, and determines that the battery has been degraded when a discharge time period which is the switching time period is shorter than a set time period.

5. The secondary battery degradation determination device as claimed in claim 1, wherein
as a process of degradation determination based on the discharge frequency, when the discharge management section starts discharge because the battery DC voltage is higher than the upper limit value, then, temporarily turns off the switch at a constant interval, maintains the switch in an off-state when the battery DC voltage measured by the voltage measurement section has become lower than the lower limit value, and repeats processes of the voltage monitoring, the comparison with the upper limit value, the temporary turning off of the switch, the comparison with the lower limit value, and the maintaining of the switch in the off-state, and if the number of times of discharge in a set time period has become greater than a set value, the degradation determination section determines that the battery has been degraded.

6. The secondary battery degradation determination device as claimed in claim 1,
the secondary battery degradation determination device being a device configured to determine degradation of each of a plurality of batteries connected in series in a power supply,
the secondary battery degradation determination device comprising:
the voltage measurement section, the discharging circuit, and the discharge management section for each battery, wherein
after the voltage measurement sections of all of the plurality of batteries have performed voltage measurement, the degradation determination section obtains an average value of measured battery DC voltages, and obtains the upper limit value and the lower limit value, using the average value as a reference.

7. The secondary battery degradation determination device as claimed in claim 1, wherein
the current limiting resistor and the switch are mounted on a same circuit board as that of the voltage measurement section.

8. The secondary battery degradation determination device as claimed in claim 1, wherein
a circuit of the current limiting resistor and the switch and a circuit of the voltage measurement section share a cable connected to the battery.

9. The secondary battery degradation determination device as claimed in claim 1, comprising:
a plurality of voltage sensors each including the voltage measurement section, the discharging circuit, and the discharge management section; and
an information processing apparatus provided single for the plurality of voltage sensors, configured to output operation instructions for the voltage sensors, perform measurement or processes regarding the voltage sensors, and collect data.

10. The secondary battery degradation determination device as claimed in claim 9, wherein
the information processing apparatus includes the degradation determination section or a section that forms a part of the degradation determination section.

11. The secondary battery degradation determination device as claimed in claim 1, comprising
an alert section configured to generate an alert, which is to be perceived by a surveillant, when the degradation determination section has determined that the battery has been degraded, wherein
the voltage measurement section, the discharging circuit, the discharge management section, the degradation determination section, and the alert section are housed in a common housing.
